(19) United States
(12) Patent Application Publication
(10) Pub. No.: US 2006/0174938 A1
(43) Pub. Date: Aug. 10, 2006

(54) Water-based electrolyte gel for dye-sensitized solar cells and manufacturing methods

(75) Inventors: Vincenza Di Palma, Cimitile (IT); Angela Cimmino, Casagiove (IT); Rossana Scaldaferri, Sapri (IT); Cosimo Carfagna, Napoli (IT); Antonella De Maria, San Giorgio a Cremano (IT); Valeria Casuscelli, Napoli (IT)

Correspondence Address: SEED INTELLECTUAL PROPERTY LAW GROUP PLLC, 701 FIFTH AVENUE, SUITE 6300, SEATTLE, WA, 98104-7092, US

(73) Assignees: STMicroelectronics S.r.l., Agrate Brianza (IT); Università degli Studi di Napoli Federico II, Napoli (IT)

(21) Appl. No.: 11/258,843

(22) Filed: Oct. 25, 2005

Related U.S. Application Data
(63) Continuation-in-part of application No. 11/051,967, filed on Feb. 4, 2005.

(51) Int. Cl. H01L 31/00

(52) U.S. Cl. 136/263; 438/57

(57) ABSTRACT

A dye-sensitized solar cell is provided having an organic compound to absorb solar radiation and donate electrons, a semiconductor to transport electrons, and a hole transporting material formed of a water-based electrolyte gel that includes a polymeric compound and a electrolyte solution. Preparation of the water based gel includes gelling a hydrophilic polymer that is present at least in a concentration, depending on molecular weight and/or degree of hydrolyses and/or degree of polymerization, sufficient to form the gel from the aqueous solution.

### BACKGROUND OF THE INVENTION

1. Field of the Invention

The present invention refers to the manufacture of Dye-Sensitized Solar Cells (DSSC). In particular, the invention concerns DSSCs comprising a water-based electrolyte gel and methods of production thereof.

2. Description of the Related Art

Dye-Sensitized Solar Cells (DSSC) are hybrid (i.e., including both organic and inorganic materials) photovoltaic cells, usually made up of three types of materials: (1) an organic compound, usually a dye or photosensitizer, to absorb light radiation and donate electrons, (2) a nanocrystalline metal oxide film, resistant to photo-corrosion, apt to transport electrons, and (3) a Hole Transporting Material (HTM), which can be liquid or solid. Like other photo-voltaic cells, DSSCs produce an electric current by conversion of solar radiation through photo-electrochemical processes.

As it is schematically illustrated in FIG. 1, a dye-sensitized solar cell 10 consists of two electrodes 12, 14 made out of glass coated with Tin oxide doped with Fluorine (SnO₂:F) or Indium and Tin oxide (ITO) or plastic coated with ITO, arranged in a sandwich-like form. One of said electrodes, the photo-electrode, is coated with a film of porous nanocrystalline semiconductive particles (usually Titanium oxide, TiO₂) on which dye molecules are made to absorb photons, whereas the other electrode, the counter-electrode 14, is coated with a catalyst (e.g., Platinum, Pt). Between the electrodes lies an electrolyte solution 16 containing a mediator for oxidized dye regeneration, the I₂/I⁻ redox couple being the most commonly used. The electrolyte solvents are usually nitriles.

The dyes most commonly used are metallo-organic complexes of Ruthenium (Ru), in particular the two dyes known as “N3 dye” and “Black dye”. These dyes have good absorption characteristics in the visible spectrum and spend relatively long times in the excited state. The performance of a DSSC heavily relies on the properties of its constituting elements (e.g., the structure, the morphology, the optical and electrical properties of the dyes and of the counter-electrode, the electrical and visco-elastic properties of the redox couple-containing electrolyte), on the respective energetic and kinetic levels of the electron transfer processes, as well as on the cell manufacturing process.

Such liquid electrolyte-based cells suffer from a number of drawbacks, mostly given by stability problems. The electrolyte solution, in fact, is susceptible to evaporation or of escaping from the cell (for example, through cracks) or of degrading with time. Other flaws include dye desorption and Platinum corrosion on the counter-electrode.

In the attempt to overcome such inconveniences, solid and quasi-solid state DSSCs have recently been developed.

The production of solid and quasi-solid state DSSCs involves the use of an electrolyte medium which is transparent, thermally stable and chemically compatible with the other components in the cell. This ensures, as in traditional liquid electrolyte DSSCs, that there is rapid reduction of the oxidized dye at the electrolyte-TiO₂ interface, sufficient ionic conductivity, and an intimate contact with the surface of the nano-structured electrode.

Despite their ease of manufacture and their lower manufacturing costs, solid state DSSCs have not proven to be particularly successful in the context of DSSC applications. In particular, solid state DSSCs exhibit conversion efficiencies that are lower than those of their liquid counterparts.

This is caused by the reduced ion mobility of the I⁻/I₃⁻ species within the polymeric matrix, as well as by the poor contact formed between the polymeric electrolyte means and the dye, due to inability of the polymer to penetrate between the pores of the TiO₂ film on which the dye is absorbed.

Gebeyehu D., et al. (Synthetic Metals, 125, 279-287, 2002), for example, have set up solid state DSSCs using poly-3-octylthiophene (P3OT) and thiophene- and isothionaphtene-based low band gap energy copolymers. The resulting devices have very low conversion efficiencies, of the order of 0.2%.

A higher conversion (1.6%) has been achieved with poly (2-methoxy-5-(2′-ethyl-hexyloxy)1,4-phenylene vinylene) (MEH-PPV) in monochromatic light (Fan, Q. et al., Chem. Phys. Lett., 347, 325-330, 2001).

A 2.56% conversion efficiency was achieved by Krüger J. et al. (Appl. Phys. Lett., n.79, 13, 2085-2087, 2001) with a solid DSSC consisting of hetero-junctions of the dye-coated TiO₂ meso-porous film and 2,2′,7,7′-tetrakis-(N,N-di-p-methoxyphenylamine)-9,9′ spirobifluorene (spiro-OMeTAD, a spirofluorene derivative), as HTM.

A good compromise between liquid and solid electrolyte means can be found in electrolytic polymeric gels. Such gels can be introduced in the cells by one of two procedures: 1) by adding a gelling material (of either high or low molecular weight) to the electrolyte solution containing the redox mediator, which will solidify the solution at a given temperature, and 2) by using polymers having good ionic conductivity, thanks to the addition of suitable plasticizers for cross-link reactions.

Cells containing gels prepared according to the first procedure have interesting conversion efficiencies and improved stability (Kubo et al., J. Phys. Chem. B, 105, 12809-12815, 2001). Good permeation between the TiO₂ nanocrystals is ensured by the fact that, above the solution-to-gel transition temperature, the solution is liquid. A good contact between the electrolyte and the dye molecules is thus ensured, and the conductivity of the resulting gel is comparable to that of the liquid electrolyte.

Murai et al. (J. Photochem. Photobiol. A: Chemistry, 148, 33-39, 2002) reports on a method to make cross-linked electrolyte gels. The gelators (or gel inducers) are made up of two components: a backbone of multi-functional polymers or oligomers, and multi-functional halogenated derivatives as cross-linkers. The results show that, although the use of such gelators does not substantially alter the photo-voltaic properties of the liquid electrolyte-containing DSSCs, nevertheless, they overcome the inconveniences given by the use of liquid electrolytes, and involve relatively simple device manufacturing procedures. The gelling procedure is carried out in situ by heating up to 80° C. after injection of the gelator in the electrolyte solution (pre-Gel) between the electrodes.

Polymeric electrolytes are desirable as they combine a high rate of ion transport with ease of set up and electrochemical stability.

Hoffman, A. S. (Advanced Drug Delivery Reviews 43, 3-12, 2002) reviewed the composition and synthesis of hydrogels in the context of biomedical applications. In particular, reference was made to gels formed from natural polymers (e.g. alginic acid, pectin, chitosan, collagen, dextran, etc.), from synthetic polymers (e.g. PEG-PLA-PEG, PEG-bis-(PLA-acrylate, etc.) and their combination (e.g. P(PEG-co-peptides), alginate-g-(PEO-PPO-PEO), etc.).

More recent studies have focused on polymeric electrolytes based on PEO (polyethylene oxide) and PAN (polyacrylonitrile) linked to Lithium salts. Ionic conductivity is improved by the addition of plasticizers (i.e., low molecular weight aprotic organic compounds having high dielectric constant value such as ethylene carbonate or propylene carbonate). Although the addition of plasticizers has the desirable effect of producing a more rapid visco-elastic response of the polymer, which in turn increases ion mobility, it has the drawback of inducing a considerable loss in dimensional stability. DSSCs in which the electrolyte consists of a polymeric mix of PAN with ethylene carbonate and propylene carbonate as plasticizers and tetrapropyl ammonium iodide (Pr₄N⁺I⁻) salt and iodine exhibit a conversion efficiency of 3%, which is rather low for normal DSSC applications.

The polymeric gels described in the literature are usually poorly cross-linked and thus do not retain the electrolyte solution to a sufficient extent.

U.S. Pat. No. 6,479,745 B2 offers an interesting solution to this problem. The electrolyte solution, with the iodine/iodide couple is made to absorb in specific cross-linked polymer films selected on the basis of their good retention and mechanical properties. The monomers used are acrylates and methacrylates or are units containing glycidyl groups in solution with suitable solvents, soaked on the porous semiconductive layer and subsequently polymerized in situ. The solvents used are ethylene carbonate, propylene carbonate, acetonitrile, ethyl acetate, cloroethane, dimethylformamide, N-methyl-2-pyrrolidone, and their respective homologues. The conversion efficiencies reach satisfactory values, up to 7%, but the manufacturing method is quite complex and not simple to carry out.

In European Patent EP 1,387,430, Komiya discloses the manufacture of cells using electrolyte gels consisting of a network structure formed by cross-link reactions between a polymeric compound including an isocyanate group and a polymeric compound including an amino group, as well as a hydroxyl and a carboxyl group, and a liquid electrolyte (non protonic solvents). The manufacturing process includes filling the cell with the gel, which subsequently cross-links in situ. Conversion efficiencies can reach 8%.

The electrolyte solutions described in the literature include low viscosity organic solvents (for example, nitrites). On the contrary, there is very little literature on the use of water in DSSCs. It has been reported, in fact, that the use of water in acetonitrile-containing electrolyte solutions, causes variations in the properties at the interface of the TiO₂ film with Ruthenium-based dyes, N3 dye, in particular as it causes an increase in the open circuit tension (Voc) and a decrease of the photo current of short circuit (Isc).

In order to improve TiO₂ /dye interfacial properties, Murakami et al. (2003) have devised a method which uses a direct treatment of the surface of the TiO₂ film with ozone and the addition of 4-tert-butylpyridine to the dye solution prior to its absorption on the oxide surface. The efficiency conversion achieved by this solution is of 2.2%.

Successful water based solution for quasi-solid state cells have not heretofore been devised.

### BRIEF SUMMARY OF THE INVENTION

An embodiment of the present invention is directed to the manufacture of water-based electrolyte gels for quasi-solid state DSSCs, which overcome the above-mentioned inconveniences of the known DSSCs.

In one embodiment, the dye sensitized solar cell (DSSC) includes an organic compound apt to absorb solar radiation and donate electrons; a semiconductor apt to transport electrons; and a hole transporting material (HTM), wherein the hole transporting material comprises a water-based electrolyte gel.

In accordance with another embodiment of the invention, a method for the production a dye sensitized solar cell comprising:

a) preparing a photo-electrode by coating a first conductive transparent support with a porous semiconductive film and with a dye;

b) preparing a counter-electrode by coating a second conductive transparent support with a catalyst;

c) providing a water-based polymer gel by polymerizing on the photo-electrode a solution of water and an acrylic monomer of Formula (I), or a mixture thereof, with a cross-linking agent, wherein Formula (I) is: 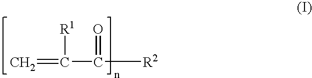
wherein n is an integer between 1 and 4, preferably n=1; R¹=H, CH₃, C₂H₅, or C₃H₇; R² is a hydroxyl group, amino group, R′ group or OR′ group, wherein R′ is a hydrocarbon residue substituted with one or more hydroxyl groups, carboxyl groups, carbonyl groups, amino groups, amide groups, glycidyl groups, ether groups, nitric groups, cyano groups, isocyanate groups, alkyloxy groups, alkylenoxy groups, or mixtures thereof; and wherein said cross-linking agent has the general formula shown in Formula (II): 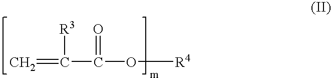
wherein R³=H, CH₃, C₂H₅, or C₃H₇; R⁴ is a hydrocarbon residue containing between 2 and 8 carbon atoms and optionally one or more oxygen atoms; and m is an integer between 2 and 4;

d) immersing the photo-electrode coated with the water based polymer gel with an electrolyte solution containing a redox electrolyte; and

e) assembling and sealing the cell.

In accordance with another embodiment of the invention, a method is provided for the production of a dye sensitized solar cell comprising:

a) preparing a photo-electrode by coating a first conductive transparent support with a porous semiconductive film and with a dye;

b) preparing a counter-electrode by coating a second conductive transparent support with a catalyst; and

c) providing a water-based electrolyte gel by mixing a hydrophilic polymer with an electrolyte solution to provide a resulting mixture, and gelling the resulting mixture, wherein said hydrophilic polymer is: vinyl polymers, polysaccharides, polylactic acid, polyethylene glycol (PEG), combinations of polysaccharides with polyethylene oxide (PEO), combinations of PEG and polycaprolactone, or mixtures thereof.

### BRIEF DESCRIPTION OF THE SEVERAL VIEWS OF THE DRAWINGS

FIG. 1 is a schematic representation of a DSSC and the enlargement shows the TiO₂ nanocrystals coated with the dye molecules and immersed in the electrolyte solution;

FIG. 2a is a photograph of the gel placed between two conductive glass supports (Soda Lime/SnO₂:F Rsh=15 Ω/Sq);

FIG. 2b is a schematic representation of the experimental apparatus for the measurement of gel conductivity.

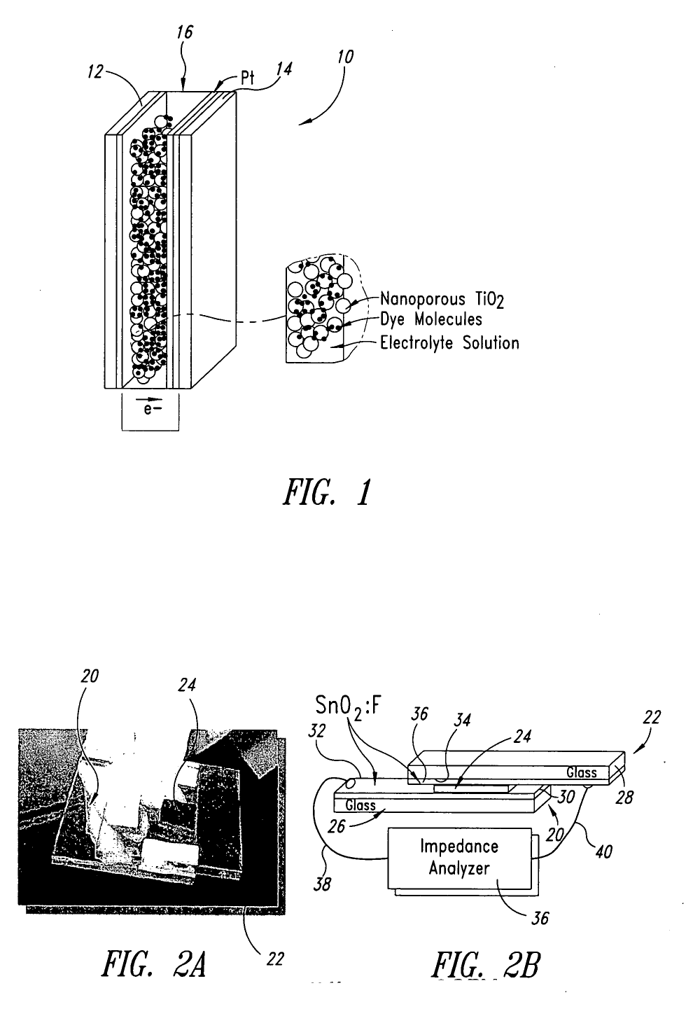

### DETAILED DESCRIPTION OF THE INVENTION

In one embodiment, the present invention provides a dye sensitized solar cell (DSSC) having an organic compound apt to absorb solar radiation and donate electrons; a semiconductor apt to transport electrons; and a hole transporting material (HTM), and which is characterized in that the hole transporting material includes a water-based electrolyte gel.

In an embodiment of the present invention, the solar cell includes a photo-electrode comprising a first conductive transparent support coated with a porous semiconductive film sensitized by an organic dye, a counter-electrode comprising a second conductive transparent glass or polymer support coated with a catalyst, and a water-based electrolyte gel including a redox electrolyte.

In another embodiment of the present invention, the water-based gel electrolyte comprises a polymeric compound and an electrolyte solution.

In a further embodiment of the present invention, the electrolyte solution is introduced into said polymeric gel either by immersion of said polymeric gel in the electrolyte solution or by direct mixing of an aqueous electrolyte solution with said polymer or aqueous solution thereof.

In a further embodiment of the present invention, the electrolyte solution includes a redox electrolyte. Examples of the redox electrolyte include: combinations of metal iodides (LiI, NaI, KI or CaI₂) with iodine; combination of metal bromides (LiBr, NaBr, KBr or CaBr₂) with bromine; pseudo-halogens (i.e., (SCN)₂/SCN⁻ and (SeCN)₂/SeCN⁻); Cobalt (II) polypyridine, phenanthroline and imidazole complexes.

In a further embodiment of the present invention, the redox electrolyte is a iodine/iodide couple.

In a further embodiment of the present invention, the redox electrolyte is present in a concentration between 0.1 and 4.0 mol/L.

In a further embodiment of the present invention, the conductive transparent support is made of a layer of glass or of a plastic polymer coated with Tin oxide doped with Fluorine (SnO₂:F) or Indium and Tin oxide (ITO) to make it conductive.

In a further embodiment of the present invention, the porous semiconductive film is made of a compound selected among the group consisting of: titanium oxide, zinc oxide, tungsten oxide, barium oxide, strontium oxide, cadmium sulfate and similar compounds, more preferably a TiO₂ nanoporous film.

In a further embodiment of the present invention, the dye is selected among the group consisting of: complexes of polypyridinic compounds with a transition metal, porphyrines, phtalocyanines, perylenes, naphtalocyanines, chinones, cianines, chinoimmines, photosynthetic pigments, and mixtures thereof.

In a further embodiment of the present invention, the gel is obtained by polymerization of an acrylic monomer of Formula (I), or a mixture thereof, with a cross-linking agent, wherein Formula (I) is: 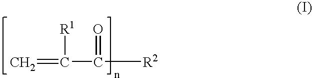
wherein n is an integer comprised between 1 and 4, preferably n=1; R¹=H, CH₃, C₂H₅, or C₃H₇; R² is a hydroxyl group, amino group, R′ group or OR′ group wherein R′ is a hydrocarbon residue substituted with one or more hydroxyl groups, carboxyl groups, carbonyl groups, amino groups, amide groups, glycidyl groups, ether groups, nitric groups, cyano groups, isocyanate groups, alkyloxy groups, alkylenoxy groups, or mixtures thereof.

“Acrylic monomer” as used herein refers to acrylic acid or its homologues, including without limitation: acrylic acid, methylacrylic acid (i.e., methacrylic acid), ethylacrylic acid and α-propylacrylic acid. An acrylic monomer of the present invention can further be in an ester, salt or amide form of an acrylic acid or its homologues. Examples of the acrylic monomer include but are not limited to: acrylic acid and its salts, ethyl acrylic acid and its salts, methacrylic acid and its salts, α-propylacrylic acid and its salts, 2-hydroxyethylmethacrylate, hydroxydiethoxyethyl methacrylate, methoxyethoxyethyl methacrylate, acrylamide, N-isopropylacrylamide, glycidyl methacrylate, 4-hydroxybutyl acrylate and the like, or mixtures thereof.

The cross-linking agent has the general formula shown in Formula (II): 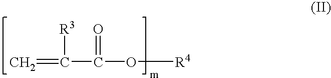
wherein R³=H, CH₃, C₂H₅, or C₃H₇; R⁴ is a hydrocarbon residue containing between 2 and 8 carbon atoms and optionally one or more oxygen atoms; and m is an integer between 2 and 4. When m is 2, examples of the cross-linking agent include but are not limited to: 1,4-butandiol diacrylate, ethyleneglycol dimethacrylate, diethyleneglycol dimethacrylate, triethyleneglycol dimethacrylate.

In a further embodiment of the present invention, the polymerization includes reacting said acrylic monomer, or a mixture thereof, and said cross-linking agent in a molar ratio ranging between 1:1 and 500:1, preferably between 10:1 and 500:1.

In a further embodiment of the present invention, the cross-linking reaction, which is thermally induced by a radical mechanism, between said acrylic monomer, or a mixture thereof, and said cross-linking agent is carried out in aqueous solution in the presence of a redox initiator.

In a further embodiment of the present invention, the water-based gel is obtained from an aqueous mixture of an acrylic monomer, or a mixture thereof, a cross-linking agent and a redox initiator in a ratio to water of 20:80 to 80:20 weight percent.

In another embodiment of the present invention, the gel is obtained by an aqueous solution of a hydrophilic polymer, wherein said hydrophilic polymer is vinyl polymers, polysaccharides, polylactic acid, polyethylene glycol (PEG), and the like polymers, combinations of polysaccharides with polyethylene oxide (PEO), combinations of PEG and polycaprolactone, or mixtures thereof.

In a further embodiment of the present invention, the vinyl polymers polyvinyl alcohol, polyvinyl pyrrolidone, polyacrylic acid and its salts, polyethylacrylic acid and its salts, polymethacrylic acid and its salts, polymethylvinyl ether, poly(2-hydroxyethyl methacrylate), polyvinyl acetate, polyvinyl amine, or the like polymers and mixtures thereof.

In a further embodiment of the present invention, the polysaccharides are starch, cellulose, pectin, guar gum, alginates, carrageenans, xanthans, dextrans or mixtures thereof.

In a further embodiment of the present invention, the hydrophilic polymer is present at least in a concentration, depending on its molecular weight and/or on its degree of hydrolysis and/or its degree of polymerization, that is sufficient for the formation of the gel from the aqueous solution.

In a further embodiment of the present invention, the hydrophilic polymer is cross-linked with aldehydes or units containing glycidyl groups and/or carboxyl groups.

In another embodiment of the present invention, the gel is obtained by direct formation of molecular complexes between a hydrophilic polymer and an aqueous solution containing the redox electrolyte.

In a further embodiment of the present invention, the hydrophilic polymer is either in the form of an aqueous solution or in the form of a powder.

In a further embodiment of the present invention, the hydrophilic polymer is vinyl polymers, polysaccharides, polylactic acid, polyethylene glycol (PEG), and the like polymers, combinations of polysaccharides with polyethylene oxide (PEO), combinations of PEG and polycaprolactone, or mixtures thereof.

In a further embodiment of the present invention, the vinyl polymers are: polyvinyl alcohol, polyvinyl pyrrolidone, polyacrylic acid and its salts, polyethylacrylic acid and its salts, polymethacrylic acid and its salts, polymethylvinyl ether, poly(2-hydroxyethyl methacrylate), polyvinyl acetate, polyvinyl amine, or the like polymers and mixtures thereof.

In another embodiment of the present invention, the polysaccharides are: starch, cellulose, pectin, guar gum, alginates, carrageenans, xanthans, dextrans or mixtures thereof.

In a further embodiment of the present invention, the hydrophilic polymer is present at least in a concentration, depending on its molecular weight and/or on its degree of hydrolysis and/or on its degree of polymerization, that is sufficient for the formation of the gel from the aqueous solution.

In a further embodiment of the present invention, the hydrophilic polymer is cross-linked with aldehydes or units containing glycidyl groups and/or carboxyl groups.

The polymeric gels according to the present invention have good electrolyte solution retention, ionic conductivity comparable to that of a liquid solution, excellent thermal stability, and good mechanical properties. Therefore, the solar cells of the present invention overcome the drawbacks of the prior art in that they minimize the release of the electrolyte solution, this being a limiting factor of the prior art.

According to another embodiment, the present invention concerns a method for the production of a dye sensitized solar cell comprising:

a) coating a first conductive transparent support with a porous semiconductive film and with a dye to provide a photo-electrode;

b) coating a second conductive transparent support with a catalyst to provide a counter-electrode;

c) providing a water-based polymer gel either by polymerization of an acrylic monomer, or a mixture thereof, with a cross-linking agent or gelling of a hydrophilic polymer with subsequent immersion of said polymeric gel in an electrolyte solution, or by direct formation of molecular complexes between at least one hydrophilic polymer and an aqueous solution containing the redox electrolyte, as explained above;

d) assembling and sealing of the three cell elements.

In a preferred embodiment of the present invention, the porous semiconductive film is: titanium oxide, zinc oxide, tungsten oxide, barium oxide, strontium oxide, cadmium sulfate and the like, preferably a nanoporous TiO₂ film.

In another embodiment of the present invention, the conductive transparent support is made of plastic (PET, PEN, PES) or glass or the like coated with ITO or SnO₂:F.

In another embodiment of the present invention, the coating of the porous semiconductive film with a dye is preferably carried out by immersion of the transparent support coated with the porous semiconductive film into a solution of said dye.

In a preferred embodiment of the present invention, the dye according to the present invention is: complexes of polypyridinic compounds with a transition metal, porphyrines, phtalocyanines, perylenes, naphtalocyanines, chinones, cianines, chinoimmines, photosynthetic pigments, and mixtures thereof.

In a further embodiment of the present invention, the dye is dissolved in a solvent selected among the group consisting of: alcohols, (e.g., ethanol), ketones (e.g., acetone), ethers (e.g., diethylether, tetrahydrofurane and the like), nitriles (e.g., acetonitrile), halogenated aliphatic hydrocarbons (e.g., chloroform), aliphatic hydrocarbons (e.g., hexane), aromatic hydrocarbons (e.g., benzene, toluene and the like), esters (e.g., ethyl acetate and the like) and mixtures thereof.

In a further embodiment of the present invention, the concentration of said dye in said solution is of at least 10⁻⁵ mol/L and preferably lies within the range of 10⁻⁵-10⁻³ mol/L.

In a further embodiment of the present invention, the conductive transparent support of step b) is made of glass or plastic coated with a thin layer of ITO or SnO₂:F and further coated with a Platinum, carbon black or gold film.

In another embodiment of the present invention, step c) is subsequent to step d) as the gel is prepared in situ after cell assembly.

In another embodiment of the present invention, the sealing materials are epoxy resins, water glass (sodium silicate), ionomer resins, aluminum foil laminated with polymer foil, or a combination thereof.

### EXAMPLE 1

### Preparation of a DSSC

Photo-electrode preparation: an SnO₂:F-coated soda lime glass support was coated with a TiO₂ film and then soaked in an amphiphilic dye solution, the dye being Z-907-dye, cis(4,4′-dicarboxylic acid) (2,2′-bipyridine-4,4′-dinonyl-2,2′-bipyridine) dithiocyanato Ru(II).

Gel preparation: A gel was prepared by thermal polymerization by reacting 99.4% (w/w) 2-hydroxy-ethyl methacrylate (2-HEMA) and 0.5% (w/w) ethylene glycol di-methacrylate (EGDMA) and then activating the radical polymerization reaction by the addition of 0.1% (w/w) ammonium persulphate and sodium meta-bi-sulphite, as redox initiators, and mixing the reagents with water in a 40:60 (w/w) ratio. The gel was then placed on the photo-electrode. This involved placing the aqueous 2-HEMA, EGDMA and redox initiators solution between the photo-electrode and a Teflon sheet (glass or PET would also have been suitable) separated by a silicon rubber spacer defining the final width of the polymeric film. At the end of the polymerization process, the Teflon sheet was easily removed. The photo-electrode surmounted by the gel was then immersed into a 0.05 mol/L I₂ and 0.5 mol/L LiI aqueous solution.

Counter-electrode preparation: an SnO₂:F-coated soda lime support was coated with a Platinum film.

Assembly and sealing: an epoxy resin was placed around the active area of the photo-electrode, the counter-electrode was then placed on top of it and the cell was put in an oven to cure the sealing resin.

### EXAMPLE 2

### Preparation of a DSSC

Photo-electrode preparation: an SnO₂:F-coated soda lime glass support was coated with a TiO₂ film and then soaked in an amphiphilic dye solution, the dye being Z-907 dye, cis(4,4′-dicarboxylic acid) (2,2′-bipyridine-4,4′-dinonyl-2,2′-bipyridine) dithiocyanato Ru(II).

Gel preparation: the polymeric film was prepared by thermal gelation of a 6% (w/w) aqueous solution of polyvinyl alcohol (125000 molecular weight, 98% hydrolyzed) placed onto the photo-electrode. This involved placing the aqueous polyvinyl alcohol solution between the photo-electrode and a Teflon sheet (glass or PET would also have been suitable) separated by a silicon rubber spacer defining the final width of the polymeric film. At the end of the gelation process, the Teflon sheet was easily removed. The photo-electrode coated by the gel was then immersed into a 0.05 mol/L I₂ and 0.5 mol/L LiI aqueous solution.

Counter-electrode preparation: an SnO₂:F-coated soda lime support was coated with a Platinum film.

Assembly and sealing: An epoxy resin was placed around the active area of the photo-electrode, then the counter-electrode was placed on top of it and the cell was put in an oven to cure the sealing resin.

### EXAMPLE 3

### Impedance Measurements

Samples of water-based electrolyte gels were prepared according to the protocol of Example 1 wherein the solutions of 2-HEMA, EGDMA and redox-initiators in water were of 30, 40, 50, 60 and 70% (w/w).

A Solartron SI 1280B Impedance Analyzer was used to measure the impedance of the films at varying gel polymer concentrations. All measurements were performed at frequency values between 0.001 and 20×10³ Hz using currents of 0.01 mA in amplitude by the set-up shown in FIGS. 2a and 2b.

More particularly, FIG. 2a shows a first electrode 20 and a second electrode 22 coupled together by a gel electrolyte 24 (shown more clearly in FIG. 2b). Each electrode 20, 22 has a glass base 26, 28, respectively. The first electrode 20 has the top surface 30 coated with tin oxide doped with fluorine (SnO₂:F) and the bottom surface 34 of the second electrode 28 is also coated with the SnO₂:F 36. An impedance analyzer 36 has a first wire 38 coupled to the coating 32 on the first electrode 20 and a second wire 40 coupled to the coating 36 on the second electrode 28.

The consistency of the measurement readings taken at different time points on the same samples suggested that the films were stable at ambient conditions and that the release of electrolyte solution was negligible. Table 1 shows the conductivity measurement readings taken at a frequency of 20 kHz.

The results were confirmed by thermal characterization techniques such as Differential Scanning Calorimetry (DSC) and Thermo-Gravimetric Analysis (TGA).

TABLE 1
CONDUCTIVITY MEASUREMENT READINGS
TAKEN AT A FREQUENCY OF 20 kHz

| Polymer weight (%) | σ ± Δσ (mS/cm) |
|---|---|
| 70 | 3.2 ± 0.1 |
| 60 | 5.4 ± 0.2 |
| 50 | 7.2 ± 0.3 |
| 40 | 12.3 ± 0.5 |
| 30 | 21.7 ± 0.9 |

Simulation of the SnO₂:F/gel/SnO₂:F system with an equivalent circuit, using a series impedance to a parallel RC, and impedance measurements at varying frequencies have shown that the SnO₂:F/gel interface capacity is of the order of μF, that is, there is good contact between the two films. At the gel polymer concentrations of the experiment, conductivity measurements ranged between 10⁻³ and 10⁻² S/cm at room temperature. Such conductivity values show that the gels produced are suitable for use in a DSSC, as the mobility of the ions within the polymeric matrix is comparable to the same in liquid solution.

### EXAMPLE 4

### “One Step” Preparation of a DSSC

Photo-electrode preparation: a SnO₂:F-coated support was coated with a TiO₂ film and then soaked into a dye solution.

Counter-electrode preparation: a soda lime support was coated with a Platinum film.

Assembly: the photo-electrode and the counter-electrode were assembled and sealed, the two electrodes being separated by a silicon rubber spacer.

Gel preparation: a gel polymer solution was prepared by mixing 5.0 g of polyvinyl alcohol (13000 molecular weight, 98% hydrolyzed) in 15 mL of a 0.05 mol/L I₂ and 0.5 mol/L LiI aqueous solution. The prepared solution was then poured into a hole made between the electrodes. The assembled cell was then left at room temperature until the polymeric solution had solidified. The cell was then completed by sealing the hole.

All of the above U.S. patents, U.S. patent application publications, U.S. patent applications, foreign patents, foreign patent applications and non-patent publications referred to in this specification and/or listed in the Application Data Sheet, are incorporated herein by reference, in their entirety.

From the foregoing it will be appreciated that, although specific embodiments of the invention have been described herein for purposes of illustration, various modifications may be made without deviating from the spirit and scope of the invention. Accordingly, the invention is not limited except as by the appended claims and the equivalents thereof.

We claim:

1. A dye sensitized solar cell, comprising:
an organic compound to absorb solar radiation and donate electrons;
a semiconductor to transport electrons; and
a hole transporting material (HTM), wherein the hole transporting material comprises a water-based electrolyte gel.

2. The dye sensitized solar cell of claim 1 wherein said organic compound is an organic dye.

3. The dye sensitized solar cell of claim 2, comprising:
a photo-electrode having a first conductive transparent support coated with a porous semiconductive film and sensitized by the organic dye;
a counter-electrode having a second conductive transparent support coated with a catalyst; and
a water-based electrolyte gel including a redox electrolyte and being positioned between the photo-electrode and the counter-electrode.

4. The dye sensitized solar cell of claim 3 wherein said water-based electrolyte gel comprises a polymeric compound and an electrolyte solution.

5. The dye sensitized solar cell of claim 4 wherein said electrolyte solution includes a redox electrolyte in a concentration of between 0.1 and 4.0 mol/L.

6. The dye sensitized solar cell of claim 3 wherein said redox electrolyte comprises an iodine/iodide couple.

7. The dye sensitized solar cell of claim 3 wherein said conductive transparent support is made of a layer of glass, a plastic polymer coated with Tin oxide doped with Fluorine (SnO₂:F) or Indium and Tin oxide (ITO).

8. The dye sensitized solar cell of claim 3 wherein said porous semiconductive film is made of a compound selected among the group consisting of: titanium oxide, zinc oxide, tungsten oxide, barium oxide, strontium oxide and cadmium sulfate.

9. The dye sensitized solar cell of claim 3 wherein said porous semiconductive film is a TiO₂ nanoporous film.

10. The dye sensitized solar cell of claim 3 wherein said dye is: complexes of polypyridinic compounds with a transition metal, porphyrines, phtalocyanines, perylenes, naphtalocyanines, chinones, cianines, chinoimmines, photosynthetic pigments, or mixtures thereof.

11. The dye sensitized solar cell of claim 3 wherein said water-based electrolyte gel comprises a polymer obtained by polymerization of an acrylic monomer of Formula (I), or a mixture thereof, with a cross-linking agent, wherein Formula (I) is: 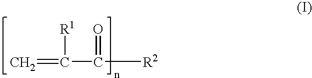
wherein,
n is an integer between 1 and 4;
each R¹ is independently H, CH₃, C₂H₅ or C₃H₇;
R² is a hydroxyl group, amino group, R′ group or OR′ group, wherein R′ is a hydrocarbon residue substituted with one or more hydroxyl groups, carboxyl groups, carbonyl groups, amino groups, amide groups, glycidyl groups, ether groups, nitric groups, cyano groups, isocyanate groups, alkyloxy groups, alkylenoxy groups or mixtures thereof; and wherein said cross-linking agent has the general formula shown in Formula (II): 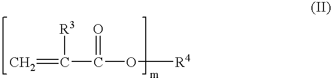
wherein,
each R³ is independently H, CH₃, C₂H₅ or C₃H₇;
R⁴ is a hydrocarbon residue containing between 2 and 8 carbon atoms and optionally one or more oxygen atoms; and
m is an integer between 2 and 4.

12. The dye sensitized solar cell of claim 11 wherein n is 1.

13. The dye sensitized solar cell of claim 11 wherein m is 2 and R⁴ is selected among the group consisting of: —CH₂—CH₂—CH₂—CH₂—, —CH₂—CH₂—, CH₂—CH₂—O—CH₂—CH₂—, CH₂—CH₂—O—CH₂—CH₂—O—CH₂—CH₂—, —CH₂—CH₂—O—CH₂—CH₂—O—CH₂—CH₂—O—CH₂—CH₂—.

14. The dye sensitized solar cell of claim 11 wherein said cross-linking agent is: 1,4-butandiole diacrylate, ethyleneglycol dimethacrylate, diethyleneglycol dimethacrylate, or triethyleneglycol dimethacrylate.

15. The dye sensitized solar cell of claim 11 wherein said polymerization includes reacting said acrylic monomer, or a mixture thereof, and said cross-linking agent in a molar ratio ranging between 1:1 and 500:1.

16. The dye sensitized solar cell of claim 11 wherein said polymerization includes reacting said acrylic monomer, or a mixture thereof, and said cross-linking agent in a molar ratio ranging between 10:1 and 500:1.

17. The dye sensitized solar cell of claim 11 wherein said polymerization is carried out using a redox initiator.

18. The dye sensitized solar cell of claim 11 wherein said water-based electrolyte gel is obtained from an aqueous mixture of the acrylic monomer, the cross-linking agent and the redox initiator in a ratio to water of 20:80 to 80:20 weight percent.

19. The dye sensitized solar cell of claim 3 wherein said water-based electrolyte gel comprises a polymer obtained by an aqueous solution of a hydrophilic polymer, wherein said hydrophilic polymer is: vinyl polymers, polysaccharides, polylactic acid, polyethylene glycol (PEG), combinations of polysaccharides with polyethylene oxide (PEO), combinations of PEG and polycaprolactone, or mixtures thereof.

20. The dye sensitized solar cell of claim 19 wherein said vinyl polymers are: polyvinyl alcohol, polyvinyl pyrrolidone, polyacrylic acid and its salts, polyethylacrylic acid and its salts, polymethacrylic acid and its salts, polymethylvinyl ether, poly(2-hydroxyethyl methacrylate), polyvinyl acetate, polyvinyl amine, or mixtures thereof.

21. The dye sensitized solar cell of claim 19 wherein said polysaccharides are: starch, cellulose, pectin, guar gum, alginates, carrageenans, xanthans, dextrans or mixtures thereof.

22. The dye sensitized solar cell of claim 19 wherein said hydrophilic polymer is present at least in a concentration, depending on its molecular weight, its degree of hydrolysis, its degree of polymerization or a combination thereof, that is sufficient for the formation of the gel from the aqueous solution.

23. The dye sensitized solar cell of claim 19 wherein said hydrophilic polymer is cross-linked with aldehydes or units containing glycidyl groups, carboxyl groups, or a combination thereof.

24. The dye sensitized solar cell of claim 3 wherein said water based electrolyte gel is obtained by direct formation of molecular complexes between a hydrophilic polymer and an aqueous solution containing the redox electrolyte.

25. The dye sensitized solar cell of claim 24 wherein said hydrophilic polymer is in the form of a powder.

26. The dye sensitized solar cell of claim 24 wherein said hydrophilic polymer is in the form of an aqueous solution.

27. The dye sensitized solar cell of claim 24 wherein said hydrophilic polymer is: vinyl polymers, polysaccharides, polylactic acid, polyethylene glycol (PEG), combinations of polysaccharides with polyethylene oxide (PEO), combinations of PEG and polycaprolactone, or mixtures thereof.

28. The dye sensitized solar cell of claim 27 wherein said vinyl polymers are: polyvinyl alcohol, polyvinyl pyrrolidone, polyacrylic acid and its salts, polyethylacrylic acid and its salts, polymethacrylic acid and its salts, polymethylvinyl ether, poly(2-hydroxyethyl methacrylate), polyvinyl acetate, polyvinyl amine or mixtures thereof.

29. The dye sensitized solar cell of claim 27 wherein said polysaccharides are: starch, cellulose, pectin, guar gum, alginates, carrageenans, xanthans, dextrans or mixtures thereof.

30. The dye sensitized solar cell of claim 27 wherein said hydrophilic polymer is present at least in a concentration, depending on its molecular weight, its degree of hydrolysis, its degree of polymerization or a combination thereof, that is sufficient for the formation of the gel from the aqueous solution.

31. The dye sensitized solar cell of claim 24 wherein said hydrophilic polymer is cross-linked with aldehydes or units containing glycidyl groups, carboxyl groups or a combination thereof.

32. A method for the production a dye sensitized solar cell comprising:
preparing a photo-electrode by coating a first conductive transparent support with a porous semiconductive film and with a dye;
preparing a counter-electrode by coating a second conductive transparent support with a catalyst; and
providing a water-based polymer gel by polymerizing on the photo-electrode a solution of water and an acrylic monomer of Formula (I), or a mixture thereof, with a cross-linking agent, wherein Formula (II) is: 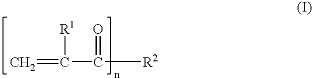
wherein,
n is an integer between 1 and 4;
each R¹ is independently H, CH₃, C₂H₅, or C₃H₇;
R² is a hydroxyl group, amino group, R′ group or OR′ group wherein R′ is a hydrocarbon residue substituted with one or more hydroxyl groups, carboxyl groups, carbonyl groups, amino groups, amide groups, glycidyl groups, ether groups, nitric groups, cyano groups, isocyanate groups, alkyloxy groups, alkylenoxy groups, or mixtures thereof; and wherein said cross-linking agent has the general formula shown in Formula (II): 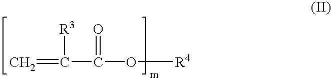
wherein,
each R³ is independently H, CH₃, C₂H₅, or C₃H₇;
R⁴ is a hydrocarbon residue containing between 2 and 8 carbon atoms and optionally one or more oxygen atoms; and
m is an integer between 2 and 4;
immersing the photo-electrode coated with the water based polymer gel in an electrolyte solution containing a redox electrolyte; and
assembling and sealing of the cell.

33. The method of claim 32 wherein n is 1.

34. The method of claim 32 wherein said electrolyte solution includes said the redox electrolyte in a concentration of between 0.1 and 4.0 mol/L.

35. The method of claim 34 wherein said redox electrolyte is an iodine/iodide couple.

36. The method of claim 32 wherein said first conductive transparent support is made of a layer of glass, a plastic polymer coated with Tin oxide doped with Fluorine (SnO₂:F) or Indium and Tin oxide (ITO).

37. The method of claim 32 wherein said porous semiconductive film is made of a compound selected among the group consisting of: titanium oxide, zinc oxide, tungsten oxide, barium oxide, strontium oxide, and cadmium sulfate.

38. The method of claim 37 wherein said porous semiconductive film is a TiO₂ nanoporous film.

39. The method of claim 32 wherein m is 2 and R₄ is: —CH₂—CH₂—CH₂—CH₂—, —CH₂—CH₂—, CH₂—CH₂—O—CH₂—CH₂—, CH₂—CH₂—O—CH₂—CH₂—O—CH₂—CH₂—, or —CH₂—CH₂—O—CH₂—CH₂—O—CH₂—CH₂—O—CH₂—CH₂—.

40. The method of claim 32 wherein said cross-linking agent is: 1,4-butandiole diacrylate, ethyleneglycol dimethacrylate, diethyleneglycol dimethacrylate, or triethyleneglycol dimethacrylate.

41. The method of claim 32 wherein said polymerization includes reacting said acrylic monomer, or a mixture thereof, and said cross-linking agent in a molar ratio ranging between 1:1 and 500:1.

42. The method of claim 32 wherein said polymerization includes reacting said acrylic monomer, or a mixture thereof, and said cross-linking agent in a molar ratio ranging between 10:1 and 500:1.

43. The method of claim 32 wherein said polymerization is carried out using a redox initiator.

44. The method of claim 32 wherein said water-based electrolyte gel is obtained from an aqueous mixture of an acrylic monomer, or a mixture thereof, a cross-linking agent and a redox initiator in a ratio to water of 20:80 to 80:20 weight percent.

45. The method of claim 32 wherein said coating of said porous semiconductive film with a dye is carried out by immersion of said first conductive transparent support coated with said porous semiconductive film into a solution of said dye.

46. The method of claim 32 wherein said dye is: complexes of polypyridinic compounds with a transition metal, porphyrines, phtalocyanines, perylenes, naphtalocyanines, chinones, cianines, chinoimmines, photosynthetic pigments, or mixtures thereof.

47. The method of claim 32 wherein said dye is dissolved in at least one solvent selected among the group consisting of: alcohols, ketones, ethers, nitrites, halogenated aliphatic hydrocarbons, aliphatic hydrocarbons, aromatic hydrocarbons, esters, and mixtures thereof.

48. The method of claim 45 wherein the concentration of the dye in said solution ranges between 10⁻⁵ and 10⁻³ mol/L.

49. The method of claim 32 wherein said second conductive transparent support is made of glass or plastic, coated with a layer of ITO or SnO₂:F and coated with a Platinum, carbon black or gold film.

50. The method of claim 32 wherein the sealing of the cell is carried out by means of a sealing agent selected among the group consisting of: epoxy resins, sodium silicate, ionomer resins, aluminum foil laminated with polymer foil, and a combination thereof.

51. A method for the production of a dye sensitized solar cell comprising:
preparing a photo-electrode by coating a first conductive transparent support with a porous semiconductive film and with a dye;
preparing a counter-electrode by coating a second conductive transparent support with a catalyst; and
providing a water-based electrolyte gel by mixing a hydrophilic polymer with a electrolyte solution to provide a resulting mixture and gelling the resulting mixture, wherein said hydrophilic polymer is: vinyl polymers, polysaccharides, polylactic acid, polyethylene glycol (PEG), combinations of polysaccharides with polyethylene oxide (PEO), combinations of PEG and polycaprolactone, or mixtures thereof.

52. The method of claim 51 wherein said electrolyte solution includes said redox electrolyte in a concentration of between 0.1 and 4.0 mol/L.

53. The method of claim 52 wherein said redox electrolyte is an iodine/iodide couple.

54. The method of claim 51 wherein said first conductive transparent support is made of a layer of glass, a plastic polymer coated with Tin oxide doped with Fluorine (SnO₂:F) or Indium and Tin oxide (ITO).

55. The method of claim 51 wherein said porous semiconductive film is made of a compound selected among the group consisting of: titanium oxide, zinc oxide, tungsten oxide, barium oxide, strontium oxide, and cadmium sulfate.

56. The method of claim 55 wherein said porous semiconductive film is a TiO₂ nanoporous film.

57. The dye sensitized solar cell of claim 51 wherein said vinyl polymers are: polyvinyl alcohol, polyvinyl pyrrolidone, polyacrylic acid and its salts, polyethylacrylic acid and its salts, polymethacrylic acid and its salts, polymethylvinyl ether, poly(2-hydroxyethyl methacrylate), polyvinyl acetate, polyvinyl amine, or mixtures thereof.

58. The dye sensitized solar cell of claim 51 wherein said polysaccharides are: starch, cellulose, pectin, guar gum, alginates, carrageenans, xanthans, dextrans or mixtures thereof.

59. The method of claim 51 wherein said water based electrolyte gel is made by a hydrophilic polymer that is present at least in a concentration, depending on its molecular weight, its degree of hydrolysis, its degree of polymerization or a combination thereof, that is sufficient for the formation of the gel from the aqueous solution.

60. The method of claim 51 wherein said hydrophilic polymer is cross-linked with aldehydes or units containing glycidyl groups, carboxyl groups or a combination thereof.

61. The method of claim 51 wherein said coating of said porous semiconductive film with a dye is carried out by immersion of said conductive transparent support coated with said porous semiconductive film into a solution of said dye.

62. The method of claim 51 wherein said dye is: complexes of polypyridinic compounds with a transition metal, porphyrines, phtalocyanines, perylenes, naphtalocyanines, chinones, cianines, chinoimmines, photosynthetic pigments, or mixtures thereof.

63. The method of claim 51 wherein said dye is dissolved in a solvent selected among the group consisting of: alcohols, ketones, ethers, nitriles, halogenated aliphatic hydrocarbons, aliphatic hydrocarbons, aromatic hydrocarbons, esters, and mixtures thereof.

64. The method of claim 61 wherein the concentration of the dye in said solution ranges between 10⁻⁵ and 10⁻³ mol/L.

65. The method of claim 51 wherein said second conductive transparent support is made of glass or plastic, coated with a layer of ITO or SnO₂:F coated with a Platinum, carbon black or gold film.

66. A method for the production of a dye sensitized solar cell comprising:
preparing a photo-electrode by coating a first conductive transparent support with a porous semiconductive film and with a dye;
preparing a counter-electrode by coating a second conductive transparent support with a catalyst;
preparing a water-based gel, on the photo-electrode, by gelling of a hydrophilic polymer wherein said hydrophilic polymer is vinyl polymers, polysaccharides, polylactic acid, polyethylene glycol (PEG), combinations of polysaccharides with polyethylene oxide (PEO), combinations of PEG and polycaprolactone, or mixtures thereof.
immersing the photo-electrode coated with water based gel in an electrolyte solution; and
assembling and sealing of the cell.

67. The method of claim 66 wherein the sealing of the cell is carried out by means of a sealing agent selected among the group consisting of: epoxy resins, sodium silicate, ionomer resins, aluminum foil laminated with polymer foil, and a combination thereof.

68. A method for the production of a dye sensitized solar cell comprising:
preparing a photo-electrode by coating a first conductive transparent support with a porous semiconductive film and with a dye to provide a photo-electrode;
preparing a counter-electrode by coating a second conductive transparent support with a catalyst to provide a counter-electrode; and
providing a water-based electrolyte gel by direct formation of molecular complexes between a hydrophilic polymer and an aqueous solution containing a redox electrolyte.

69. The method of claim 68 wherein the hydrophilic polymer is vinyl polymers, polysaccharides, polylactic acid, polyethylene glycol (PEG), combinations of polysaccharides with polyethylene oxide (PEO), combinations of PEG and polycaprolactone, or mixtures thereof.

70. A method for the production of a dye sensitized solar cell comprising:
preparing a photo-electrode by coating a first conductive transparent support with a porous semiconductive film and with a dye to provide a photo-electrode;
preparing a counter-electrode by coating a second conductive transparent support with a catalyst;
assembling and sealing the photo-electrode and counter-electrode, separated by a spacer;
providing a water-based electrolyte gel by pouring a solution of a hydrophilic polymer and an aqueous solution containing a redox electrolyte between the photo-electrode and the counter-electrode by means of a previously made hole between the electrodes or on the counter-electrode and allowing the solution to gel by direct formation of molecular complexes; and
sealing the hole.

71. The method of claim 70 wherein said water-based electrolyte gel comprises a polymeric compound and an electrolyte solution.

72. The method of claim 71 wherein said electrolyte solution includes said redox electrolyte in a concentration of between 0.1 and 4.0 mol/L.

73. The method of claim 70 wherein said redox electrolyte is an iodine/iodide couple

74. The method of claim 70 wherein said conductive transparent support is made of a layer of glass or of a plastic polymer coated with Tin oxide doped with Fluorine (SnO₂:F) or Indium and Tin oxide (ITO).

75. The method of claim 70 wherein said porous semiconductive film is made of a compound selected among the group consisting of: titanium oxide, zinc oxide, tungsten oxide, barium oxide, strontium oxide, and cadmium sulfate.

76. The method of claim 75 wherein said porous semiconductive film is a TiO₂ nanoporous film.

77. The method of claim 70 wherein said water based electrolyte gel is made by a hydrophilic polymer that is present at least in a concentration, depending on its molecular weight, its degree of hydrolysis, its degree of polymerization or a combination thereof, that is sufficient for the formation of the gel from the aqueous solution.

78. The method of claim 70 wherein said hydrophilic polymer is cross-linked with aldehydes or units containing glycidyl groups, carboxyl groups or a combination thereof.

79. The method of claim 70 wherein said coating of said porous semiconductive film with a dye is carried out by immersion of said first conductive transparent support coated with said porous semiconductive film into a solution of said dye.

80. The method of claim 70 wherein said dye is complexes of polypyridinic compounds with a transition metal, porphyrines, phtalocyanines, perylenes, naphtalocyanines, chinones, cianines, chinoimmines, photosynthetic pigments, or mixtures thereof.

81. The method of claim 70 wherein said dye is dissolved in at least one solvent selected among the group consisting of: alcohols, ketones, ethers, nitrites, halogenated aliphatic hydrocarbons, aliphatic hydrocarbons, aromatic hydrocarbons, esters, and mixtures thereof.

82. The method of claim 81 wherein the concentration of the dye in said solution ranges between 10⁻⁵ and 10⁻³ mol/L.

83. The method of claim 70 wherein said second conductive transparent support is made of glass or plastic, coated with a layer of ITO or SnO₂:F coated with a Platinum, carbon black or gold film.

84. The method of claim 71 wherein the sealing of the cell is carried out by means of a sealing agent selected among the group consisting of: epoxy resins, sodium silicate, ionomer resins, aluminum foil laminated with polymer foil, and a combination thereof.

85. A dye sensitized solar cell obtained by a method comprising:
preparing a photo-electrode by coating a first conductive transparent support with a porous semiconductive film and with a dye;
preparing a counter-electrode by coating a second conductive transparent support with a catalyst;
assembling and sealing the photo-electrode and counter-electrode, separated by a spacer;
providing a water-based electrolyte gel by pouring a solution of a hydrophilic polymer and an aqueous solution containing a redox electrolyte between the photo-electrode and the counter-electrode by means of a previously made hole between the electrodes or on the counter-electrode and allowing the solution to gel by direct formation of molecular complexes; and
sealing the hole.

86. A dye sensitized solar cell of claim 85 wherein said hydrophilic polymer is in the form of a powder or an aqueous solution.

87. A dye sensitized solar cell of claim 85 wherein said hydrophilic polymer is: vinyl polymers, polysaccharides, polylactic acid, polyethylene glycol, or mixtures thereof.

88. The dye sensitized solar cell of claim 87 wherein said vinyl polymers are: polyvinyl alcohol, polyvinylpyrrolidone, polyacrylic acid and its salts, polyethylacrylic acid and its salts, polymethacrylic acid and its salts, or polymethylvinyl ether.

89. The dye sensitized solar cell of claim 87 wherein said polysaccharides are: starch, cellulose, pectin, guar gum, alginates, carrageenans, xanthans, dextrans or mixtures thereof.
